(19) United States
(12) Patent Application Publication
(10) Pub. No.: US 2025/0384902 A1
(43) Pub. Date: Dec. 18, 2025

(54) SEMICONDUCTOR STRUCTURE AND PREPARATION METHOD THEREOF

(71) Applicant: XIAMEN INDUSTRIAL TECHNOLOGY RESEARCH INSTITUTE CO., LTD., Xiamen (CN)

(72) Inventors: Huayi LIU, Xiamen (CN); WEN-MING LEE, Xiamen (CN); Yuhuang CHEN, Xiamen (CN); Jiayu YIN, Xiamen (CN); Tianlong PAN, Xiamen (CN)

(73) Assignee: XIAMEN INDUSTRIAL TECHNOLOGY RESEARCH INSTITUTE CO., LTD., Xiamen (CN)

(21) Appl. No.: 19/021,318

(22) Filed: Jan. 15, 2025

(30) Foreign Application Priority Data
Jun. 18, 2024 (CN) 202410788891.5

(51) Int. Cl. G11C 5/06; H10B 63/00; H10N 70/20

(52) U.S. Cl. CPC G11C 5/063; H10B 63/22; H10N 70/20

(57) ABSTRACT

A semiconductor structure and a preparation method thereof are provided. The semiconductor structure includes: a substrate; a plurality of memory cells arranged in a first direction and a second direction, each of the memory cells including a first transistor, a first memristor, a second transistor, and a second memristor; where the first and second directions are parallel to a plane of the substrate and intersect; and a plurality of first and second bit lines extending in the first direction. In every two adjacent rows of memory cells arranged in the first direction, all the first memristors in a first row and all the second memristors in a second row are connected to a same first bit line, and all the second memristors in the first row and all the first memristors in the second row are connected to a same second bit line.

### CROSS REFERENCE TO THE RELATED APPLICATIONS

The present application is based upon and claims priority to Chinese Patent Application No. 202410788891.5 filed on Jun. 18, 2024, the entire contents of which are incorporated herein by reference.

### TECHNICAL FIELD

The present disclosure relates to the technical field of semiconductors, and in particular, to a semiconductor structure and a preparation method thereof.

### BACKGROUND

A resistive random access memory (RRAM) is a non-volatile memory for storing information by using the variable resistance characteristic of a material, and has the advantages of low power consumption, high density, high read and write speed, high durability, and the like.

Among existing memory arrays, most of them have a 2T2R structure, that is, include two transistors and two RRAMs. However, the two RRAMs in the existing 2T2R structure are connected to a same bit line. When a single RRAM is operated, the other transistor faces the risk of breakdown caused by high leakage voltage.

### SUMMARY

The present disclosure provides a semiconductor structure and a preparation method thereof to at least solve the above technical problems in the related art.

According to a first aspect of the present disclosure, a semiconductor structure is provided, including:
a substrate;
a plurality of memory cells arranged in a first direction and a second direction; where each of the plurality of memory cells includes a first transistor, a first memristor connected to the first transistor, a second transistor, and a second memristor connected to the second transistor; where the first direction and the second direction are parallel to a plane of the substrate and intersect; and
a plurality of first bit lines extending in the first direction and a plurality of second bit lines extending in the first direction; where in every two adjacent rows of memory cells arranged in the first direction, the first memristors in a first row and the second memristors in a second row are connected to a same first bit line, and the second memristors in the first row and the first memristors in the second row are connected to a same second bit line.

In one implementation, the semiconductor structure may further include:
a plurality of source lines extending in the first direction; where in a same row of memory cells extending in the first direction, the first transistors and the second transistors may be connected to a same source line.

In one implementation, the semiconductor structure may further include:
a first conductive connection layer disposed on the first memristor and the second memristor and electrically connected to the first memristor and the second memristor; and
a second conductive connection layer disposed on the first conductive connection layer and including a first sub conductive connection layer and a second sub conductive connection layer; where in the every two adjacent rows of memory cells arranged in the first direction, the first memristor in the first row is electrically connected through the first sub conductive connection layer to the second memristor in the second row that is diagonally distributed from the first memristor in the first row, and the second memristor in the first row is electrically connected through the second sub conductive connection layer to the first memristor in the second row that is diagonally distributed from the second memristor in the first row.

In one implementation, the first bit line may be disposed on the first sub conductive connection layer and electrically connected to the first sub conductive connection layer; and
the second bit line may be disposed on the second sub conductive connection layer and electrically connected to the second sub conductive connection layer.

In one implementation, the semiconductor structure may further include:
a plurality of first word lines extending in the second direction and a plurality of second word lines extending in the second direction; where the first transistors arranged in the second direction in a same row may be connected to the first word line, and the second transistors arranged in the second direction in a same row may be connected to the second word line.

According to a second aspect of the present disclosure, a method for preparing a semiconductor structure is provided, including:
providing a substrate;
forming a plurality of memory cells arranged in a first direction and a second direction, each of the plurality of memory cells including a first transistor, a first memristor connected to the first transistor, a second transistor, and a second memristor connected to the second transistor; where the first direction and the second direction are parallel to a plane of the substrate and intersect; and
forming a plurality of first bit lines extending in the first direction and a plurality of second bit lines extending in the first direction; where in every two adjacent rows of memory cells arranged in the first direction, the first memristors in a first row and the second memristors in a second row are connected to a same first bit line, and the second memristors in the first row and the first memristors in the second row are connected to a same second bit line.

In one implementation, the method may further include:
before forming the plurality of first bit lines and the plurality of second bit lines, forming a plurality of source lines extending in the first direction; where in a same row of memory cells extending in the first direction, all the first transistors and all the second transistors are connected to a same source line.

In one implementation, the method may further include:
before forming the plurality of first bit lines and the plurality of second bit lines, forming a first conductive connection layer disposed on the first memristor and the second memristor; where the first conductive connection layer is electrically connected to the first memristor and the second memristor; and
forming a second conductive connection layer disposed on the first conductive connection layer and including a first sub conductive connection layer and a second sub conductive connection layer; where in the every two adjacent rows of memory cells arranged in the first direction, the first memristor in the first row is electrically connected through the first sub conductive connection layer to the second memristor in the second row that is diagonally distributed from the first memristor in the first row, and the second memristor in the first row is electrically connected through the second sub conductive connection layer to the first memristor in the second row that is diagonally distributed from the second memristor in the first row.

In one implementation, the first bit line may be disposed on the first sub conductive connection layer and electrically connected to the first sub conductive connection layer; and
the second bit line may be disposed on the second sub conductive connection layer and electrically connected to the second sub conductive connection layer.

In one implementation, the method may further include:
before forming the plurality of first bit lines and the plurality of second bit lines, forming a plurality of first word lines extending in the second direction and a plurality of second word lines extending in the second direction; where the first transistors arranged in the second direction in a same row are connected to the first word line, and the second transistors arranged in the second direction in a same row are connected to the second word line.

According to the semiconductor structure and the preparation method thereof of the present disclosure, the first memristor and the second memristor in each memory cell are connected to different bit lines, so that the voltage of the two bit lines can be controlled separately, which can greatly avoid the risk of breakdown caused by high leakage voltage due to the fact that adjacent transistors share a source line during startup operation, and reduce electric leakage of adjacent transistors. Meanwhile, in every two adjacent rows of memory cells arranged in the first direction, all the first memristors in the first row and all the second memristors in the second row are connected to the same first bit line, and all the second memristors in the first row and all the first memristors in the second row are connected to the same second bit line, so that only two bit lines are still formed in two rows of memory cells, without increasing the cell area of the device or changing the array density.

It should be understood that the content described in this section is not intended to identify critical or important features of the embodiments of the present disclosure, and is not used to limit the scope of the present disclosure either. Other features of the present disclosure will be easily understood through the following description.

### BRIEF DESCRIPTION OF THE DRAWINGS

By reading the following detailed description with reference to the accompanying drawings, the above and other objectives, features and advantages of the exemplary embodiments of the present disclosure will become easier to understand. In the drawings, several embodiments of the present disclosure are shown in an exemplary and non-limiting manner.

In the drawings, the same or corresponding reference numerals denote the same or corresponding parts.

FIG. 1 is a top view of a semiconductor structure according to an embodiment of the present disclosure.

FIG. 2 is a cross-sectional view along line A-A′ in FIG. 1.

FIG. 3 is a circuit diagram of a semiconductor structure according to an embodiment of the present disclosure.

FIG. 4 is a flowchart of a method for preparing a semiconductor structure according to an embodiment of the present disclosure.

FIG. 5A and FIG. 5B are schematic diagrams of a semiconductor structure according to an embodiment of the present disclosure in a preparation process.

### DETAILED DESCRIPTION OF THE EMBODIMENTS

In order to make the objectives, features, and advantages of the present disclosure more apparent and easier to understand, the technical solutions in the embodiments of the present disclosure will be clearly and completely described below with reference to the accompanying drawings therein. Apparently, the described embodiments are merely a part rather than all of the embodiments of the present disclosure. All other embodiments obtained by those skilled in the art based on the embodiments of the present disclosure without any creative efforts shall fall within the protection scope of the present disclosure.

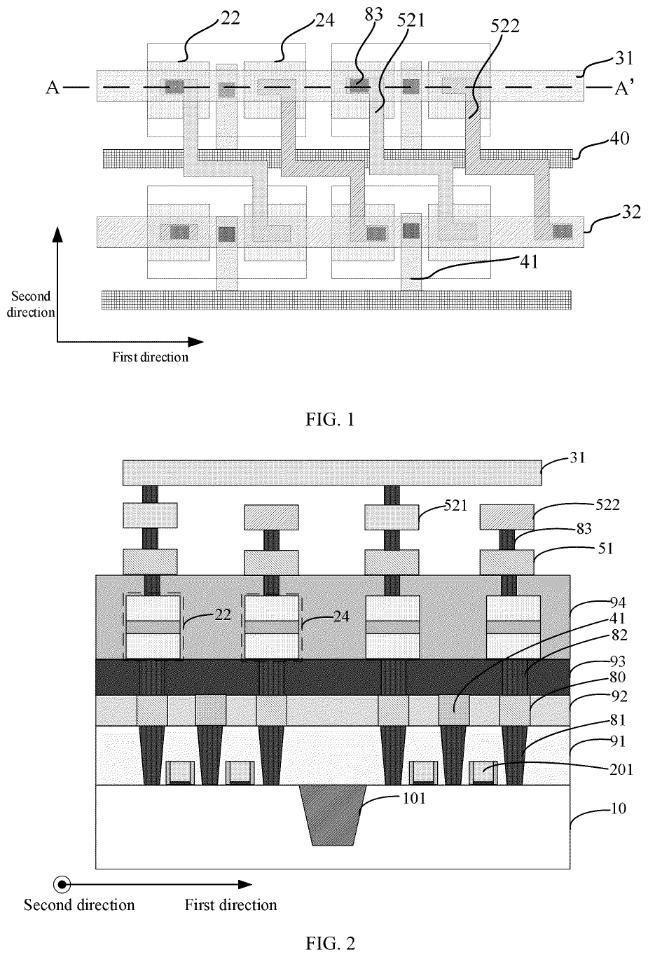

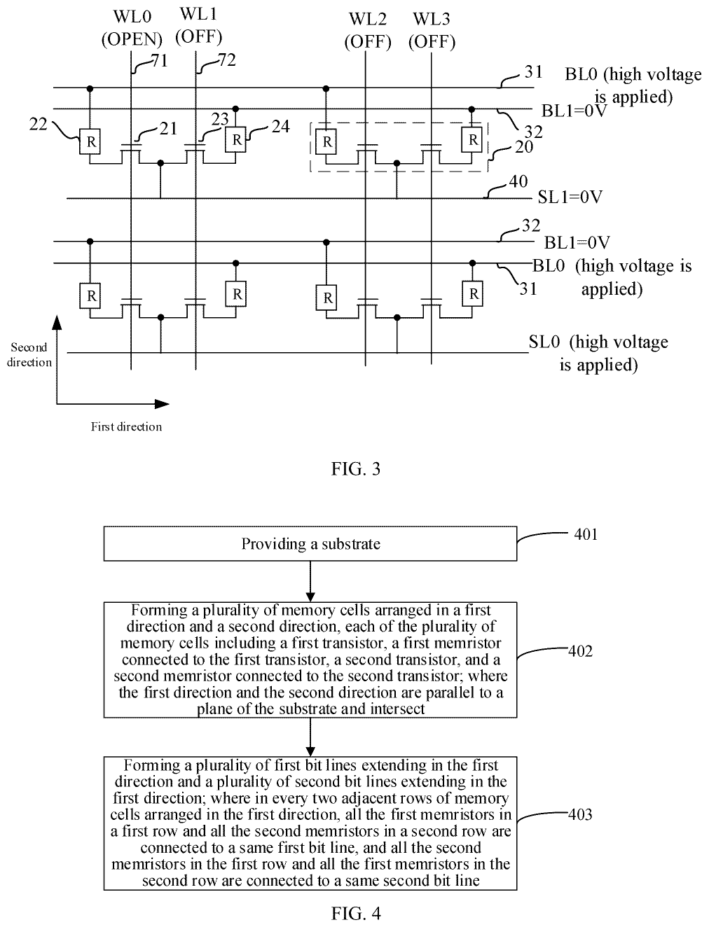

Embodiments of the present disclosure provide a semiconductor structure. FIG. 1 is a top view of a semiconductor structure according to an embodiment of the present disclosure, FIG. 2 is a cross-sectional view along line A-A′ in FIG. 1, and FIG. 3 is a circuit diagram of a semiconductor structure according to an embodiment of the present disclosure.

As shown in FIG. 1 to FIG. 3, the semiconductor structure includes:
a substrate 10;
a plurality of memory cells 20 arranged in a first direction and a second direction; where each of the plurality of memory cells 20 includes a first transistor 21, a first memristor 22 connected to the first transistor 21, a second transistor 23, and a second memristor 24 connected to the second transistor 23; where the first direction and the second direction are parallel to a plane of the substrate 10 and intersect; and
a plurality of first bit lines 31 extending in the first direction and a plurality of second bit lines 32 extending in the first direction; where in every two adjacent rows of memory cells 20 arranged in the first direction, all the first memristors 22 in a first row and all the second memristors 24 in a second row are connected to a same first bit line 31, and all the second memristors 24 in the first row and all the first memristors 22 in the second row are connected to a same second bit line 32.

In an embodiment, the substrate 10 may be an elemental semiconductor material substrate (such as a silicon substrate, a germanium substrate, or the like), a composite semiconductor material substrate (such as a germanium-silicon substrate or the like), a silicon on insulator (SOI) substrate, a germanium on insulator (GOI) substrate, or the like.

A shallow trench isolation structure 101 is formed in the substrate 10.

In an embodiment, the semiconductor structure further includes: a first interlayer dielectric layer 91, a second interlayer dielectric layer 92, a third interlayer dielectric layer 93, and a fourth interlayer dielectric layer 94 sequentially stacked on the substrate 10.

The material of the first interlayer dielectric layer 91 includes, but is not limited to an insulating material such as silicon oxide, silicon nitride, silicon oxynitride or the like; the second interlayer dielectric layer 92 may be a metal interlayer dielectric layer, such as made of aluminum oxide, zinc oxide or the like; the third interlayer dielectric layer 93 may be a nitride doped silicon carbide (NDC) film; and the material of the fourth interlayer dielectric layer 94 includes, but is not limited to silicon oxide, silicon nitride, silicon oxynitride or other insulating materials.

The semiconductor structure further includes: a first contact via/plug 81 disposed in the first interlayer dielectric layer 91; a first metal layer 80 disposed in the second interlayer dielectric layer 92; and a second contact via 82 disposed in the third interlayer dielectric layer 93. The first metal layer 80 is connected to the substrate 10 through the first contact via 81 and connected to the first memristor 22 and the second memristor 24 through the second contact via 82.

The material of the first metal layer 80 includes, but is not limited to copper. The first contact via 81 and the second contact via 82 may be of a double-layer structure, and materials of the first contact via 81 and the second contact via 82 may include titanium nitride disposed on an outer layer and tungsten disposed on an inner layer.

As shown in FIG. 3, each memory cell 20 includes the first transistor 21 and the second transistor 23. As shown in FIG. 2, the first transistor and the second transistor each include a gate structure 201 disposed on the substrate 10, and a source region (not shown) and a drain region (not shown) which are disposed on two sides of the gate structure 201 within the substrate 10. Sources of the first transistor 21 and the second transistor 23 are connected to form a common source structure.

The first memristor 22 and the second memristor 24 are disposed in the fourth interlayer dielectric layer 94, and the first memristor 22 and the second memristor 24 include a lower electrode, a resistive layer (also called resistive switching layer), and an upper electrode, respectively.

The material of the lower electrode includes, but is not limited to titanium nitride; the material of the resistive layer includes, but is not limited to transition metal oxides, such as hafnium oxide, aluminum oxide and the like; and the material of the upper electrode includes, but is not limited to titanium nitride.

In an embodiment, as shown in FIG. 1 and FIG. 3, the semiconductor structure further includes a plurality of source lines 40 extending in the first direction. In a same row of memory cells 20 extending in the first direction, all the first transistors 21 and all the second transistors 23 are connected to a same source line 40.

Specifically, as shown in FIG. 1, the source line 40 is connected to the first transistor 21 and the second transistor 23 through a connection line 41.

In an embodiment, the source line 40 is arranged in parallel to the first bit line 31 and the second bit line 32 to form a common SL and common BL structure, which can reduce power consumption, improve read and write speed, and improve signal integrity.

In an embodiment, the semiconductor structure further includes: a first conductive connection layer 51 which is disposed on the first memristor 22 and the second memristor 24 and is electrically connected to the first memristor 22 and the second memristor 24; and
a second conductive connection layer disposed on the first conductive connection layer 51 and including a first sub conductive connection layer 521 and a second sub conductive connection layer 522. In the every two adjacent rows of memory cells 20 arranged in the first direction, the first memristor 22 in the first row is electrically connected through the first sub conductive connection layer 521 to the second memristor 24 in the second row that is diagonally distributed from the first memristor 22 in the first row, and the second memristor 24 in the first row is electrically connected through the second sub conductive connection layer 522 to the first memristor 22 in the second row that is diagonally distributed from the second memristor 24 in the first row.

Specifically, as shown in FIG. 2, the first conductive connection layer 51 is electrically connected to the first memristor 22 and the second memristor 24 through a third contact via 83.

The second conductive connection layer is used for connecting the first memristor 22 and the second memristor 24 in the two adjacent rows. Specifically, as shown in FIG. 1, for example, the first sub conductive connection layer 521 is used for connecting the first memristor 22 of the first memory cell 20 in the first row and the second memristor 24 of the first memory cell 20 in the second row, and connecting the first memristor 22 of the second memory cell 20 in the first row and the second memristor 24 of the second memory cell 20 in the second row. The second sub conductive connection layer 522 is used for connecting the second memristor 24 of the first memory cell 20 in the first row and the first memristor 22 of the second memory cell 20 in the second row.

Of course, the first memristors and the second memristors in the two adjacent rows are not limited to the connection method shown in FIG. 1. For example, the first sub conductive connection layer 521 is used for connecting the first memristor 22 of the second memory cell 20 in the first row and the second memristor 24 of the first memory cell 20 in the second row; and the second sub conductive connection layer 522 is used for connecting the second memristor 24 of the first memory cell 20 in the first row and the first memristor 22 of the first memory cell 20 in the second row, and connecting the second memristor 24 of the second memory cell 20 in the first row and the first memristor 22 of the second memory cell 20 in the second row.

The first conductive connection layer 51 and the second conductive connection layer are also connected through the third contact via 83.

In the embodiment of the present disclosure, two adjacent rows of first memristors and second memristors that need to be connected are connected by the first sub conductive connection layer and the second sub conductive connection layer, and then connected to the same first bit line or second bit line, so that the two adjacent rows of first memristors and second memristors do not interfere with each other during connection to avoid crosstalk.

As shown in FIG. 1 to FIG. 3, in every two adjacent rows of memory cells 20 arranged in the first direction, all the first memristors 22 in the first row and all the second memristors 24 in the second row are connected to the same first bit line 31, and all the second memristors 24 in the first row and all the first memristors 22 in the second row are connected to the same second bit line 32.

In an embodiment, the first bit line 31 is disposed on the first sub conductive connection layer 521 and electrically connected to the first sub conductive connection layer 521; the second bit line 32 is disposed on the second sub conductive connection layer 522 and electrically connected to the second sub conductive connection layer 522.

The first bit line 31 and the first sub conductive connection layer 521 are connected by the third contact via 83, and the second bit line 32 and the second sub conductive connection layer 522 are connected by the third contact via 83.

It should be explained that the third contact via 83, the first conductive connection layer 51, the first sub conductive connection layer 521, the second sub conductive connection layer 522, and the first bit line 31 in FIG. 2 should all be wrapped by dielectric layers.

In the embodiments of the present disclosure, the first memristor and the second memristor in each memory cell are connected to different bit lines, so that the voltage of the two bit lines can be controlled separately, which can greatly avoid the risk of breakdown caused by high leakage voltage due to the fact that adjacent transistors share a source line during startup operation, and reduce electric leakage of adjacent transistors. Meanwhile, in every two adjacent rows of memory cells arranged in the first direction, all the first memristors in the first row and all the second memristors in the second row are connected to the same first bit line, and all the second memristors in the first row and all the first memristors in the second row are connected to the same second bit line, so that only two bit lines are still formed in two rows of memory cells, without increasing the cell area of the device or changing the array density.

In a specific embodiment, as shown in FIG. 3, a high voltage is applied to the source line SL0 to turn on the word line WL0, so the first memristor 22 and the first transistor 21 of the first memory cell 20 in the second row are turned on. Then, the same high voltage as the source line SL0 is applied to the first bit line BL0, which can pull up the voltage of the second transistor 23 of the first memory cell 20 in the second row, so that two ends of the second memristor 24 and the second transistor 23 achieve zero voltage difference to avoid electric leakage of the second transistor 23.

In an embodiment, as shown in FIG. 3, the semiconductor structure further includes: a plurality of first word lines 71 extending in the second direction and a plurality of second word lines 72 extending in the second direction. All the first transistors 21 arranged in the second direction in a same row are connected to the first word line 71, and all the second transistors 23 arranged in the second direction in a same row are connected to the second word line 72.

An embodiment of the present disclosure further provides a method for preparing a semiconductor structure. FIG. 4 is a flowchart of a method for preparing a semiconductor structure according to an embodiment of the present disclosure. As shown in FIG. 4, the method for preparing a semiconductor structure includes:

Step 401, providing a substrate;

Step 402, forming a plurality of memory cells arranged in a first direction and a second direction, each of the plurality of memory cells including a first transistor, a first memristor connected to the first transistor, a second transistor, and a second memristor connected to the second transistor; where the first direction and the second direction are parallel to a plane of the substrate and intersect; and

Step 403, forming a plurality of first bit lines extending in the first direction and a plurality of second bit lines extending in the first direction; where in every two adjacent rows of memory cells arranged in the first direction, all the first memristors in a first row and all the second memristors in a second row are connected to a same first bit line, and all the second memristors in the first row and all the first memristors in the second row are connected to a same second bit line.

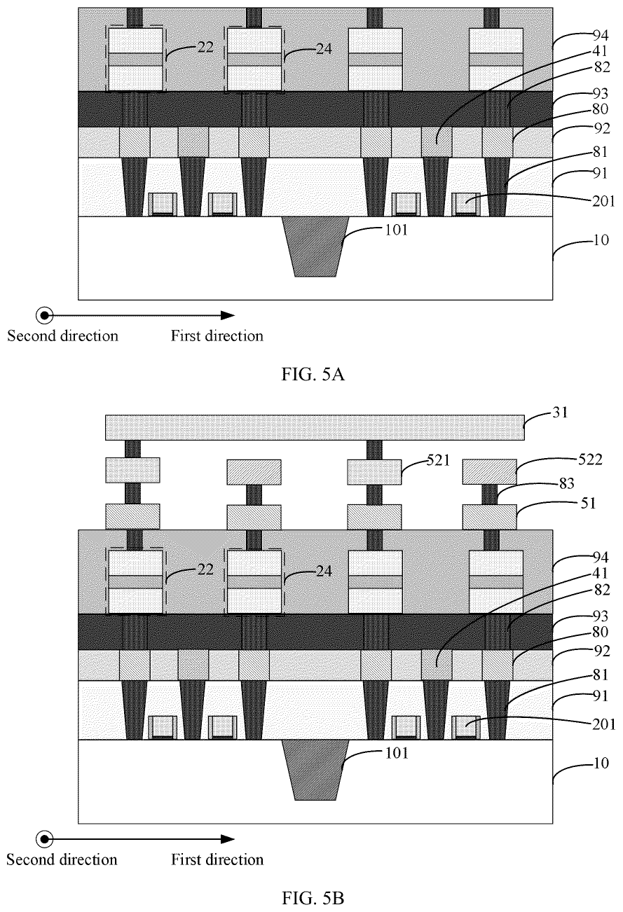

The method for preparing a semiconductor structure according to the embodiment of the present disclosure is further described below in detail in combination with specific embodiments. FIG. 5A and FIG. 5B are schematic diagrams of a semiconductor structure according to an embodiment of the present disclosure in a preparation process.

First, with reference to FIG. 5A, a substrate 10 is provided.

In an embodiment, the substrate 10 may be an elemental semiconductor material substrate (such as a silicon substrate, a germanium substrate, or the like), a composite semiconductor material substrate (such as a germanium-silicon substrate or the like), a silicon on insulator (SOI) substrate, a germanium on insulator (GOI) substrate, or the like.

A shallow trench isolation structure 101 is formed in the substrate 10.

With continued reference to FIG. 5A, a first interlayer dielectric layer 91, a second interlayer dielectric layer 92, a third interlayer dielectric layer 93 and a fourth interlayer dielectric layer 94 are sequentially formed on the substrate 10.

In actual operation, the first interlayer dielectric layer 91, the second interlayer dielectric layer 92, the third interlayer dielectric layer 93 and the fourth interlayer dielectric layer 94 may be formed by chemical vapor deposition (CVD), physical vapor deposition (PVD), atomic vapor deposition (ALD), or other deposition methods.

The material of the first interlayer dielectric layer 91 includes, but is not limited to an insulating material such as silicon oxide, silicon nitride, silicon oxynitride or the like; the second interlayer dielectric layer 92 may be a metal interlayer dielectric layer, such as made of aluminum oxide, zinc oxide or the like; the third interlayer dielectric layer 93 may be a nitride doped silicon carbide (NDC) film; and the material of the fourth interlayer dielectric layer 94 includes, but is not limited to silicon oxide, silicon nitride, silicon oxynitride or other insulating materials.

With continued reference to FIG. 5A, a first contact via 81 is formed in the first interlayer dielectric layer 91; a first metal layer 80 is formed in the second interlayer dielectric layer 92; a second contact via 82 is formed in the third interlayer dielectric layer 93. The first metal layer 80 is connected to the substrate 10 through the first contact via 81 and connected to the first memristor 22 and the second memristor 24 through the second contact via 82.

The material of the first metal layer 80 includes, but is not limited to copper. The first contact via 81 and the second contact via 82 may be of a double-layer structure, and materials of the first contact via 81 and the second contact via 82 may include titanium nitride disposed on an outer layer and tungsten disposed on an inner layer.

With continued reference to FIG. 5A and FIG. 3, a plurality of memory cells 20 arranged in a first direction and a second direction are formed, each of the memory cells 20 includes a first transistor 21, a first memristor 22 connected to the first transistor 21, a second transistor 23, and a second memristor 24 connected to the second transistor 23; and the first direction and the second direction are parallel to a plane of the substrate and intersect.

Specifically, a gate structure 201 is formed on the substrate 10, and a source region (not shown) and a drain region (not shown) are formed on two sides of the gate structure 201 within the substrate 10. The gate structure 201, the source region, and the drain region constitute the first transistor 21 and the second transistor 23.

The first memristor 22 and the second memristor 24 are formed in the fourth interlayer dielectric layer 94, and the first memristor 22 and the second memristor 24 include a lower electrode, a resistive layer, and an upper electrode, respectively.

The material of the lower electrode includes, but is not limited to titanium nitride; the material of the resistive layer includes, but is not limited to transition metal oxides, such as hafnium oxide, aluminum oxide and the like; and the material of the upper electrode includes, but is not limited to titanium nitride.

In an embodiment, the preparation method further includes: forming a plurality of source lines 40 extending in the first direction. In a same row of memory cells 20 extending in the first direction, all the first transistors 21 and all the second transistors 23 are connected to a same source line 40.

Specifically, as shown in FIG. 1, the source line 40 is connected to the first transistor 21 and the second transistor 23 through a connection line 41.

In an embodiment, the source line 40 is arranged in parallel to a first bit line 31 and a second bit line 32. The parallel arrangement can avoid crosstalk between the source line and the first bit line 31 and second bit line 32.

Next, the method further includes: before forming the first bit lines 31 and the second bit lines 32, forming a plurality of first word lines 71 extending in the second direction and a plurality of second word lines 72 extending in the second direction. All the first transistors 21 arranged in the second direction in the same row are connected to the first word line 71, and all the second transistors 23 arranged in the second direction in the same row are connected to the second word line 72 (see FIG. 3).

With reference to FIG. 5B, before the first bit lines 31 and the second bit lines 32 are formed, a first conductive connection layer 51 disposed on the first memristor 22 and the second memristor 24 is formed, and the first conductive connection layer 51 is electrically connected to the first memristor 22 and the second memristor 24; and
a second conductive connection layer disposed on the first conductive connection layer 51 is formed, and the second conductive connection layer includes a first sub conductive connection layer 521 and a second sub conductive connection layer 522. In the every two adjacent rows of memory cells 20 arranged in the first direction, the first memristor 22 in the first row is electrically connected through the first sub conductive connection layer 521 to the second memristor 24 in the second row that is diagonally distributed from the first memristor 22 in the first row, and the second memristor 24 in the first row is electrically connected through the second sub conductive connection layer 522 to the first memristor 22 in the second row that is diagonally distributed from the second memristor 24 in the first row.

Specifically, as shown in FIG. 5B, the first conductive connection layer 51 is electrically connected to the first memristor 22 and the second memristor 24 through a third contact via 83.

The second conductive connection layer is used for connecting the first memristor 22 and the second memristor 24 in the two adjacent rows. Specifically, as shown in FIG. 1, for example, the first sub conductive connection layer 521 is used for connecting the first memristor 22 of the first memory cell 20 in the first row and the second memristor 24 of the first memory cell 20 in the second row, and connecting the first memristor 22 of the second memory cell 20 in the first row and the second memristor 24 of the second memory cell 20 in the second row; and the second sub conductive connection layer 522 is used for connecting the second memristor 24 of the first memory cell 20 in the first row and the first memristor 22 of the second memory cell 20 in the second row.

Of course, the first memristors and the second memristors in the two adjacent rows are not limited to the connection method shown in FIG. 1. For example, the first sub conductive connection layer 521 is used for connecting the first memristor 22 of the second memory cell 20 in the first row and the second memristor 24 of the first memory cell 20 in the second row; and the second sub conductive connection layer 522 is used for connecting the second memristor 24 of the first memory cell 20 in the first row and the first memristor 22 of the first memory cell 20 in the second row, and connecting the second memristor 24 of the second memory cell 20 in the first row and the first memristor 22 of the second memory cell 20 in the second row.

The first conductive connection layer 51 and the second conductive connection layer are also connected through the third contact via 83.

In the embodiment of the present disclosure, two adjacent rows of first memristors and second memristors that need to be connected are connected by the first sub conductive connection layer and the second sub conductive connection layer, and then connected to the same first bit line or second bit line, so that the two adjacent rows of first memristors and second memristors do not interfere with each other during connection to avoid crosstalk.

Next, with continued reference to FIG. 5B and FIG. 1, a plurality of first bit lines 31 extending in the first direction and a plurality of second bit lines 32 extending in the first direction are formed. In every two adjacent rows of memory cells 20 arranged in the first direction, all the first memristors 22 in the first row and all the second memristors 24 in the second row are connected to a same first bit line 31, and all the second memristors 24 in the first row and all the first memristors 22 in the second row are connected to a same second bit line 32.

In an embodiment, the first bit line 31 is disposed on the first sub conductive connection layer 521 and electrically connected to the first sub conductive connection layer 521; the second bit line 32 is disposed on the second sub conductive connection layer 522 and electrically connected to the second sub conductive connection layer 522.

The first bit line 31 and the first sub conductive connection layer 521 are connected by the third contact via 83, and the second bit line 32 and the second sub conductive connection layer 522 are connected by the third contact via 83.

It should be explained that the third contact via 83, the first conductive connection layer 51, the first sub conductive connection layer 521, the second sub conductive connection layer 522, and the first bit line 31 in FIG. 2 should all be wrapped by dielectric layers.

It should be understood that the steps may be reordered, added or deleted by using the flows in various forms, which are shown above. For example, the steps recorded in the present disclosure may be performed concurrently, in order, or in a different order, provided that the desired result of the technical solutions disclosed in the present disclosure can be achieved, which is not limited herein.

In addition, the terms “first” and “second” are merely used for a description purpose, and cannot be interpreted as indicating or implying relative importance or implicitly indicating the number of the indicated technical features. Therefore, the features defined by “first” and “second” may explicitly or implicitly include at least one of the features. In the description of the present disclosure, “a plurality of” means two or more, unless otherwise specified.

What are described above are merely specific embodiments of the present disclosure, and are not intended to limit the scope of protection of the present disclosure, and any changes or substitutions that can readily occur to those skilled in the art within the scope of technologies disclosed in the present disclosure should fall within the scope of protection of the present disclosure. Therefore, the scope of protection of the present disclosure shall be subject to the scope of protection of the claims.

1. A semiconductor structure, comprising:
a substrate;
a plurality of memory cells arranged in a first direction and a second direction; wherein each of the plurality of memory cells comprises a first transistor, a first memristor connected to the first transistor, a second transistor, and a second memristor connected to the second transistor; wherein the first direction and the second direction are parallel to a plane of the substrate and intersect; and
a plurality of first bit lines extending in the first direction and a plurality of second bit lines extending in the first direction; wherein in every two adjacent rows of memory cells arranged in the first direction, the first memristors in a first row and the second memristors in a second row are connected to a same first bit line, and the second memristors in the first row and the first memristors in the second row are connected to a same second bit line.

2. The semiconductor structure according to claim 1, further comprising:
a plurality of source lines extending in the first direction; wherein in a same row of memory cells extending in the first direction, the first transistors and the second transistors are connected to a same source line.

3. The semiconductor structure according to claim 1, further comprising:
a first conductive connection layer disposed on the first memristor and the second memristor and electrically connected to the first memristor and the second memristor; and
a second conductive connection layer disposed on the first conductive connection layer and comprising a first sub conductive connection layer and a second sub conductive connection layer; wherein in the every two adjacent rows of memory cells arranged in the first direction, the first memristor in the first row is electrically connected through the first sub conductive connection layer to the second memristor in the second row that is diagonally distributed from the first memristor in the first row, and the second memristor in the first row is electrically connected through the second sub conductive connection layer to the first memristor in the second row that is diagonally distributed from the second memristor in the first row.

4. The semiconductor structure according to claim 3, wherein
the first bit line is disposed on the first sub conductive connection layer and electrically connected to the first sub conductive connection layer; and
the second bit line is disposed on the second sub conductive connection layer and electrically connected to the second sub conductive connection layer.

5. The semiconductor structure according to claim 1, further comprising:
a plurality of first word lines extending in the second direction and a plurality of second word lines extending in the second direction; wherein the first transistors arranged in the second direction in a same row are connected to the first word line, and the second transistors arranged in the second direction in a same row are connected to the second word line.

6. A method for preparing a semiconductor structure, comprising:
providing a substrate;
forming a plurality of memory cells arranged in a first direction and a second direction, each of the plurality of memory cells comprising a first transistor, a first memristor connected to the first transistor, a second transistor, and a second memristor connected to the second transistor; wherein the first direction and the second direction are parallel to a plane of the substrate and intersect; and
forming a plurality of first bit lines extending in the first direction and a plurality of second bit lines extending in the first direction; wherein in every two adjacent rows of memory cells arranged in the first direction, the first memristors in a first row and the second memristors in a second row are connected to a same first bit line, and the second memristors in the first row and the first memristors in the second row are connected to a same second bit line.

7. The method for preparing the semiconductor structure according to claim 6, further comprising:
before forming the plurality of first bit lines and the plurality of second bit lines, forming a plurality of source lines extending in the first direction; wherein in a same row of memory cells extending in the first direction, the first transistors and the second transistors are connected to a same source line.

8. The method for preparing the semiconductor structure according to claim 6, further comprising:
before forming the plurality of first bit lines and the plurality of second bit lines, forming a first conductive connection layer disposed on the first memristor and the second memristor; wherein the first conductive connection layer is electrically connected to the first memristor and the second memristor; and
forming a second conductive connection layer disposed on the first conductive connection layer and comprising a first sub conductive connection layer and a second sub conductive connection layer; wherein in the every two adjacent rows of memory cells arranged in the first direction, the first memristor in the first row is electrically connected through the first sub conductive connection layer to the second memristor in the second row that is diagonally distributed from the first memristor in the first row, and the second memristor in the first row is electrically connected through the second sub conductive connection layer to the first memristor in the second row that is diagonally distributed from the second memristor in the first row.

9. The method for preparing the semiconductor structure according to claim 8, wherein
the first bit line is disposed on the first sub conductive connection layer and electrically connected to the first sub conductive connection layer; and
the second bit line is disposed on the second sub conductive connection layer and electrically connected to the second sub conductive connection layer.

10. The method for preparing the semiconductor structure according to claim 6, further comprising:
before forming the plurality of first bit lines and the plurality of second bit lines, forming a plurality of first word lines extending in the second direction and a plurality of second word lines extending in the second direction; wherein the first transistors arranged in the second direction in a same row are connected to the first word line, and the second transistors arranged in the second direction in a same row are connected to the second word line.
